(19) United States
(12) Patent Application Publication
(10) Pub. No.: US 2026/0101691 A1
(43) Pub. Date: Apr. 9, 2026

(54) INHIBITOR-FREE GAPFILL PROCESS METHOD AND HARDWARE

(71) Applicant: Tokyo Electron Limited, Tokyo (JP)

(72) Inventor: Jianping ZHAO, Austin, TX (US)

(73) Assignee: Tokyo Electron Limited, Tokyo (JP)

(21) Appl. No.: 18/908,408

(22) Filed: Oct. 7, 2024

(51) Int. Cl. H01L 21/311; H01J 37/32; H01L 21/02

(52) U.S. Cl. CPC H10P 50/282; H01J 37/32422; H01J 37/32568; H10P 14/69433; H01J 37/32082; H01J 2237/332; H01J 2237/334

(57) ABSTRACT

Aspects of the present disclosure provide an inhibitor-free method for filling a recessed feature of a substrate. For example, the inhibitor-free method can include providing a substrate that has a recessed feature, forming a first layer of an insulating material on the substrate to cover a sidewall and bottom of the recessed feature, removing a portion of the first layer such that the recessed feature with the first layer remaining therein slopes outward, and forming a second layer of the insulating material on the substrate to cover the first layer remaining in the recessed feature.

### FIELD OF THE INVENTION

The present disclosure relates to semiconductor processing, and, in particular, to gap-filling methods and related apparatuses.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Semiconductor fabrication involves multiple varied steps and processes. One typical fabrication process is known as photolithography (also called microlithography). Photolithography uses radiation, such as ultraviolet or visible light, to generate fine patterns in a semiconductor device design. Many types of semiconductor devices, such as diodes, transistors, and integrated circuits, can be constructed using semiconductor fabrication techniques including photolithography, etching, film deposition, surface cleaning, metallization, and so forth.

In semiconductor processing, it is often needed to fill insulating materials into high aspect ratio (HAR) patterns, such as shallow trench isolation (STI), inter-metal dielectrics (IMDs), pre-metal dielectrics (PMDs), nanosheets, etc., and required that the HAR patterns are void free and seamless.

### SUMMARY

Aspects of the present disclosure provide an inhibitor-free method for filling a recessed feature of a substrate. For example, the inhibitor-free method can include providing a substrate that has a recessed feature, forming a first layer of an insulating material on the substrate to cover a sidewall and bottom of the recessed feature, removing a portion of the first layer such that the recessed feature with the first layer remaining therein slopes outward, and forming a second layer of the insulating material on the substrate to cover the first layer remaining in the recessed feature. For example, the portion of the first layer can include corners of the first layer. In an embodiment, the corners of the first layer contact with each other. In some embodiments, the insulating material can include SiN, and the first layer remaining in the recessed feature can have a —NH₂ terminated surface at the corners that is modified to be a —N or —NH terminated surface so less growth is on the —N or —NH terminated surface at the corners than a bottom surface of the recessed feature which still has a —NH₂ terminated surface. In an embodiment, the inhibitor-free method can further include removing a portion of the second layer such that the recessed feature with the first layer and the second layer remaining therein slopes outward.

In an embodiment, the portion of the first layer can be removed in an ion bombardment process. For example, the ion bombardment process can be included in a purely physical etch process. In an embodiment, ion energy applied to and angle distribution of atomic positive ions created in the ion bombardment process can be controlled by adjusting an electrical field where the substrate is positioned therewithin. In some embodiments, the electrical field can be formed between a first electrode and a second electrode that is coupled to the substrate, with a first alternating current (AC) voltage being applied to the first electrode and a second AC voltage or a direct current (DC) voltage being applied to the second electrode. For example, the first AC voltage can include a high radio frequency (RF) voltage, and the second AC voltage can include a low RF voltage. As another example, the DC voltage can include a pulsing DC voltage.

Aspects of the present disclosure also provide a plasma system that is used in association with a plasma chamber to fill a recessed feature of a semiconductor structure. For example, the plasma system can include a first electrode disposed within the plasma chamber and a first alternating current (AC) generator coupled to the first electrode and configured to generate and apply a first AC voltage to the first electrode, a second electrode disposed within the plasma chamber, and a second AC generator coupled to the second electrode and configured to generate and apply a second AC voltage to the second electrode. In an embodiment, the first AC generator and the second AC generator can be controlled to adjust the first AC voltage and the second AC voltage, respectively, such that ion energy applied to and angle distribution of atomic positive ions generated in the plasma chamber can be controlled to anisotropically impact and remove a portion of an insulating material formed on a sidewall and bottom of a recessed feature of a semiconductor structure positioned within an electric field generated between the first electrode and the second electrode and the recessed feature with the insulating material remaining therein can slope outward.

In an embodiment, the first AC generator can include a first radio frequency (RF) generator, the first AC voltage can include a first RF voltage, the second AC generator can include a second RF generator, and the second AC voltage can include a second RF voltage. For example, the second RF voltage can have a lower frequency than the first RF voltage, and the semiconductor structure can be coupled to the second electrode.

In an embodiment, the plasma system can further include a direct current (DC) power supply coupled to the second electrode and configured to supply a DC voltage to the second electrode, wherein the DC power supply can be controlled to adjust the DC voltage such that the ion energy applied to and the angle distribution of the atomic positive ions can be further controlled to anisotropically impact and remove the portion of the insulating material formed on the sidewall and the bottom of the recessed feature of the semiconductor structure and the recessed feature with the insulating material remaining therein slopes outward. For example, the DC power supply can include a pulsing DC power supply, and the DC voltage includes a pulsing DC voltage.

Aspects of the present disclosure also provide another plasma system that is used in association with a plasma chamber to fill a recessed feature of a semiconductor structure. For example, the another plasma system can include a first electrode disposed within the plasma chamber, a first alternating current (AC) generator coupled to the first electrode and configured to generate and apply a first AC voltage to the first electrode, a second electrode disposed within the plasma chamber, and a direct current (DC) power supply coupled to the second electrode and configured to supply a DC voltage to the second electrode. In an embodiment, the first AC generator and the DC power supply can be controlled to adjust the first AC voltage and the DC voltage, respectively, such that ion energy applied to and angle distribution of atomic positive ions generated in the plasma chamber can be controlled to anisotropically impact and remove a portion of an insulating material formed on a sidewall and bottom of a recessed feature of a semiconductor structure positioned within an electric field generated between the first electrode and the second electrode and the recessed feature with the insulating material remaining therein can slope outward.

In some embodiments, the plasma system can further include a second AC generator coupled to the second electrode and configured to generate and apply a second AC voltage to the second electrode, wherein the second AC generator can be controlled to adjust the second AC voltage such that the ion energy applied to and the angle distribution of the atomic positive ions can be further controlled to anisotropically impact and remove the portion of the insulating material formed on the sidewall and the bottom of the recessed feature of the semiconductor structure and the recessed feature with the insulating material remaining therein can slope outward.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIGS. 1A-1C show the formation of a void within an insulating material filled in a recessed feature of a semiconductor structure;

FIGS. 2A-2C show the formation of a seam impact the etch performance of an insulating material filled in a recessed feature of a semiconductor structure;

FIGS. 3A and 3B show filling a recessed feature of a semiconductor structure with an insulating material after the recessed feature is exposed to an inhibitor;

FIG. 4 is a flow chart of an exemplary inhibitor-free method that is used to fill a recessed feature of a semiconductor structure according to some embodiments of the present disclosure;

FIGS. 5A-5E are simplified cross-sectional views of the semiconductor structure that illustrate the profile of gapfill as the semiconductor structure is processed according to the steps of the method according to some embodiments of the present disclosure;

FIG. 6 is a schematic diagram illustrating a first exemplary plasma system that can fill a recessed feature of a semiconductor structure according to some embodiments of the present disclosure;

FIG. 7 is a schematic diagram illustrating a second exemplary plasma system that can fill a recessed feature of a semiconductor structure according to some embodiments of the present disclosure; and

FIG. 8 is a schematic diagram illustrating a third exemplary plasma system that can fill a recessed feature of a semiconductor structure according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

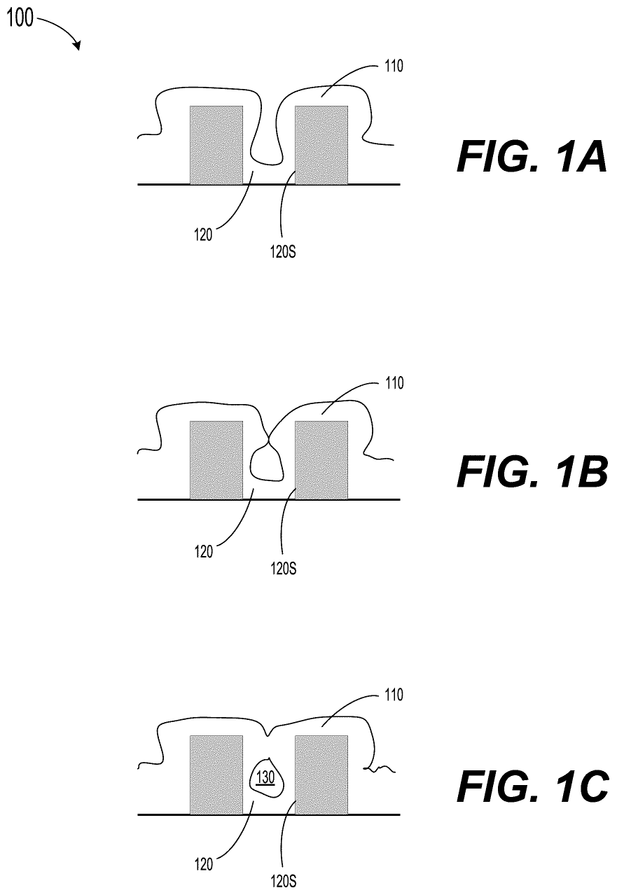

In a recessed feature (e.g., gap) filling (e.g., deposition) process, more insulating material (e.g., dielectrics) or conductive material may be deposited on the upper region than on the lower region of a sidewall of a gap and therefore create overhang or even close-up formations at the entry to the gap. As shown in FIG. 1A, an insulating material 110 is deposited to fill a gap 120 of a semiconductor structure (e.g., a substrate) 100, with more insulating material 110 formed on the upper region than on the lower region of a sidewall 120S of the gap 120. As the gap filling process proceeds, the top portion of the insulating material (or conductive material) 110 may be closed prematurely, as shown in FIG. 1B. As a result, a void 130 may be left within the lower portion of the insulating material (or conductive material) 110, as shown in FIG. 1C, which would impact the capacitance of the insulating material 110 (or the conductivity performance of the conductive material 110).

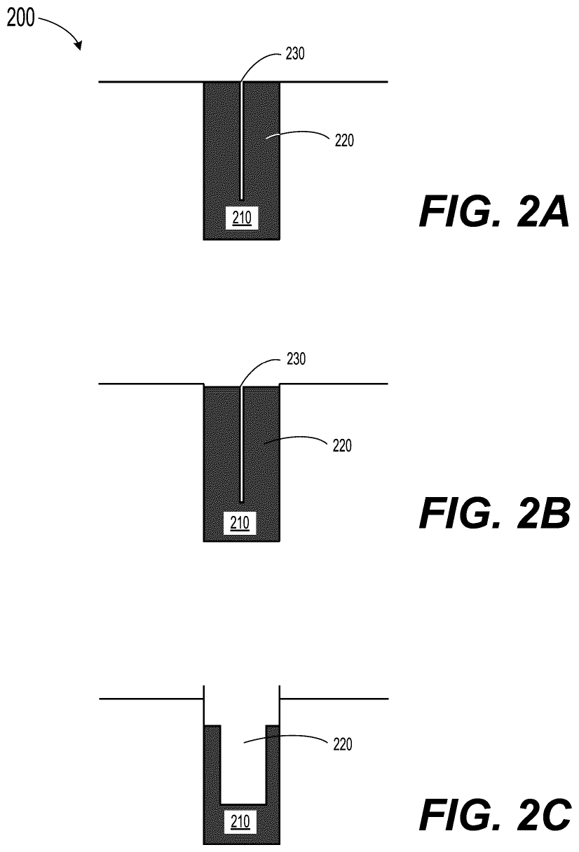

In the gap filling process, a seam may also be formed within an insulating material that is used to fill a gap. As shown in FIG. 2A, an insulating material 210 is deposited to fill a gap 220 of a semiconductor structure 200, with a seam 230 vertically formed within the insulating material 210. As an etching process (e.g., a wet etching process) is performed subsequently, the excessive portion of the insulating material 210 formed outside of the gap 220 can be etched and removed, as shown in FIG. 2B. However, the etching agent used in the wet etching process may flow through the seam 230, and, as a result, the upper portion of the insulating material 210 may be etched and removed undesirably, as shown in FIG. 2C.

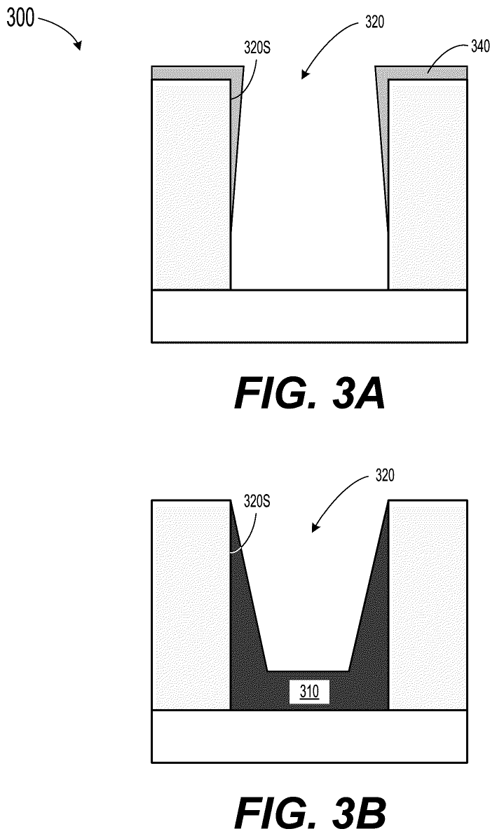

An inhibition-based mechanism, which promotes a bottom-up fill mechanism, can be used to solve the above-described void and seam issues. For example, a semiconductor structure 300 that has a recessed feature (e.g., a gap) 320 can be exposed to an inhibitor (e.g., NF₃ or similar halogen-containing chemistry) 340 to selectively inhibit deposition near the upper region of a sidewall 320S of the gap 320, as shown in FIG. 3A. As a deposition process is performed subsequently, less insulating material 310 may thus be deposited on the upper region than on the lower region of the sidewall 320S of the gap 320, and, therefore, the gap 320 with the insulating material 310 formed on the sidewall 320S may slope outward (i.e., the insulating material 310 being bottom-up or V-shaped growth), as shown in FIG. 3B, allowing the gap 320 to be completely filled by additional insulating material 310 subsequently in a void-free and/or seam-free manner.

However, the NF₃-containing inhibitor 340 may incorporate the fluorine impurities in the insulating material 310 (e.g., a silicon-containing filler), which may negatively affect physical and electrical characteristics (e.g., causing higher wet etch rate and greater leakage current and breakdown voltage, etc.) of a semiconductor device being formed from the semiconductor structure 300. Further, the NF₃-containing inhibitor (e.g., halogen species) 340 may also attack metals in a processing chamber where the deposition process takes place, and the metal that is etched from the processing chamber may be deposited on the semiconductor structure 300 being processed.

The void and seam issues may also be addressed by using a deposition-etch-deposition (dep-etch-dep) process. In the dep-etch-dep process, a first layer of an insulating material is deposited to cover a sidewall and bottom of a gap of a semiconductor structure until the top portion of the first layer is almost closed or just closed, resulting in a partial filling of the gap; a reactive etching agent (e.g., NF₃) is then introduced to etch the top portion of the first layer to widen or reopen the entry to the gap; the etched surface of the first layer is passivated by exposing the semiconductor structure to a passivation gas, e.g., molecular oxygen (O₂), ozone (O₃), nitrous oxide (N₂O), molecular nitrogen (N₂), etc., that can chemically react with the surface of the first layer to remove halogen species (e.g., fluorine) that may be incorporated therein; and a second layer of the insulating material is further deposited to fill the gap. More than one cycle of etching, passivating and depositing may be performed until the gap is filled with the insulating material completely.

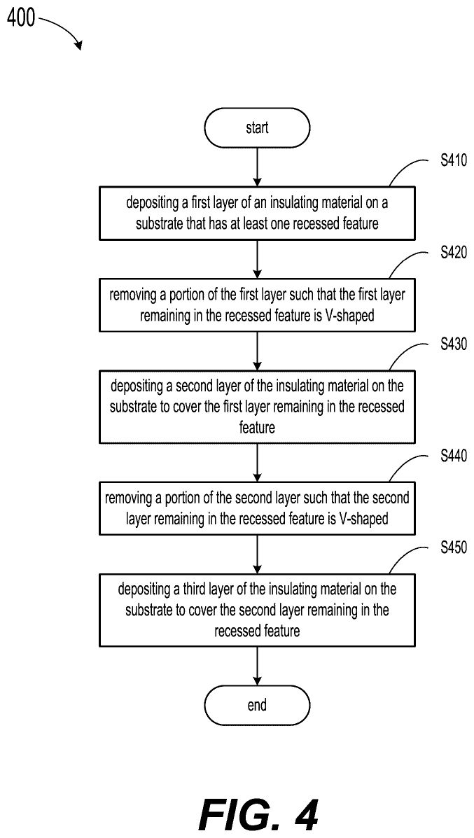

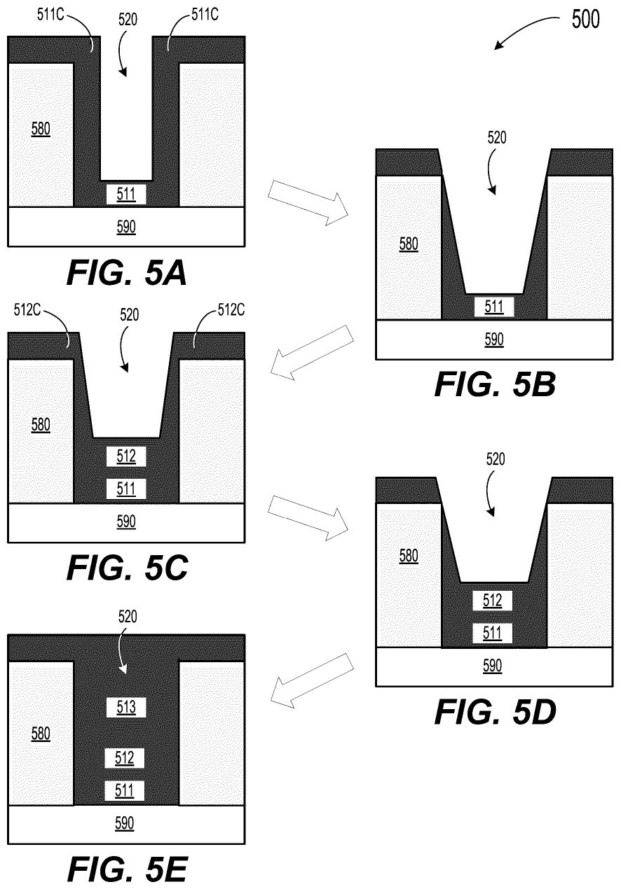

FIG. 4 is a flowchart of an exemplary inhibitor-free method 400 that fills a recessed feature of a semiconductor structure 500 according to some embodiments of the present disclosure. FIGS. 5A-5E are simplified cross-sectional views of the semiconductor structure 500 that illustrate the profile of gapfill as the semiconductor structure 500 is processed according to the steps of the method 400 according to some embodiments of the present disclosure. In various embodiments, some of the steps of the method 400 shown can be performed concurrently or in a different order than shown, can be substituted by other method steps, or can be omitted. Additional method steps can also be performed as desired.

The method 400 can start with step S410, at which a first layer of an insulating material 511 is deposited in a first deposition process on a substrate (or a wafer) 590 that has at least one recessed feature 520 formed thereon and between various adjacent features 580, such as metal lines, transistor gates, etc., as shown in FIG. 5A. For example, the recessed feature 520 can include high aspect ratio (HAR) patterns, such as shallow trench isolation (STI), inter-metal dielectrics (IMDs), pre-metal dielectrics (PMDs), nanosheets, etc. In an embodiment, the substrate 590 can be loaded and positioned in a processing chamber where the deposition process takes place. In another embodiment, the insulating material 511 can include a silicon-containing material, e.g., silicon oxide (SiO), silicon nitride (SiN), etc. In some embodiments, the first deposition process can include vapor-based deposition processes, such as atomic layer deposition (ALD), plasma enhanced atomic layer deposition (PEALD), remote plasma atomic layer deposition (RPALD), chemical vapor deposition (CVD), plasma enhanced chemical vapor deposition (PECVD), remote plasma chemical vapor deposition (RPCVD), inductively coupled plasma chemical vapor deposition (ICP CVD), high density plasma chemical vapor deposition (HDP CVD), or others.

In an embodiment, in the ALD process the substrate 590 can be exposed to a gas phase distribution of a first reactant, such as a silicon-containing precursor (e.g., H₂SiCl₂ (dichlorosilane, DCS), SiH₄, H₉NSi₃ (Trisilylamine, TSA), etc.), in a dose provided to the processing chamber; molecules of the first reactant are adsorbed onto the surface of the substrate 590 (e.g., the sidewall and bottom of the gap 520), including chemisorbed species and/or physisorbed molecules of the first reactant; the processing chamber is then evacuated and purged by using nitrogen (N₂), hydrogen (H₂), inert gas such as argon (Ar), neon (Ne) and helium (He), or a combination thereof to remove the first reactant remaining in the gas phase; a second reactant, such as an oxygen-containing gas, a nitrogen-containing gas (e.g., NH₃, N₂/H₂, etc.), etc., is subsequently introduced into the processing chamber so that some of the oxygen/nitrogen molecules react with the first reactant absorbed to the sidewall and bottom of the gap 520 and the first layer 511 (i.e., the silicon-containing material, e.g., silicon oxide (SiO), silicon nitride (SiN), etc.) is formed conformally on the sidewall and bottom of the gap 520; and the processing chamber may be evacuated and purged again to remove unbound second reactant molecules and byproducts. The second reactant can react with the absorbed first reactant immediately or only after a source of activation is applied temporally. The reaction of the second reactant with the absorbed first reactant can be driven by thermal energy and/or plasma energy. Corners 511C of the first layer 511 after the SiN conformal deposition usually end with NH₂ functional groups. These NH₂ functional groups will be preferentially modified by plasma, untraviolet (UV) light, ion or electron beam, etc. to —N and —NH functional groups, thus slowing down the growth per cycle (GPC) of the first layer 511 on the upper sidewall relative to the bottom and lower sidewall of the gap 520.

In an embodiment, the first deposition process performed at step S410 can be stopped just prior to or just after the corners (i.e., top portion) 511C of the first layer 511 contact each other and the first layer 511 is almost closed or just closed. For example, step S410 can be executed multiple times, i.e., more than one cycle of the deposition of the first reactant, the purging, the deposition of the second reactant and the purging being performed, until the corners 511C of the first layer 511 contact or almost contact each other.

The method 400 can proceed to step S420, at which a portion of the first layer 511 is removed such that the first layer 511 remaining in the gap 520 is V-shaped and the gap 520 with the first layer 511 remaining therein slopes outward, as shown in FIG. 5B. In an embodiment, a portion of the first layer 511, e.g., the corners 511C of the first layer 511, can be etched anisotropically solely in a purely physical etch process such as an ion bombardment process (e.g., sputtering, ion milling, etc.) or other ways (e.g., electron, photon, surface temperature flashing) such that the etched first layer 511 is V-shaped and the gap 520 with the first layer 511 remaining therein slopes outward. For example, in the ion bombardment process atomic positive ions such as inert elements (e.g., argon (Ar), helium (He), etc.) can be created in a plasma contained in the processing chamber, applied with a high energy (e.g., greater than 500 eV) that is created in the processing chamber (e.g., using electrodes in the case of a DC potential or radio frequency (RF) excitation, a waveguide in the case of microwaves, etc.), and thus accelerated to anisotropically impact and remove the corners 511C of the first layer 511, and atoms will be ejected into a gas phase to be pumped away by a vacuum system. In an embodiment, the ion energy applied to and the angle distribution of the atomic positive ions (e.g., Ar⁺. He⁺, etc.) can be controlled, e.g., by adjusting radio frequency (RF) bias or pulsing DC, such that the etched first layer 511 can have a desired V-shape. According to the present disclosure, the sole use of the ion bombardment process can cause the first layer 511 remaining in the gap 520 to be V-shaped. Therefore, neither inhibitor (e.g., NF₃) nor the passivation process is needed for forming the V-shaped first layer 511. Also in step S420, the processing chamber can be evacuated and purged by using N₂, H₂, inert gas such as Ar, Ne and He, or a combination thereof.

The method 400 can proceed to step S430, at which a second layer of the insulating material 512 is deposited in a second deposition process on the substrate 590 to cover the first layer 511 remaining in the gap 520, as shown in FIG. 5C. The second deposition process can also include vapor-based deposition processes, such as ALD, PEALD, RPALD, CVD, PECVD, RPCVD, ICP CVD, HDP CVD, or others. In some embodiments, the second deposition process performed at step S430 can be stopped just prior to or just after corners (i.e., top portion) 512C of the second layer 512 contact each other and the second layer 512 is almost closed or just closed.

The method 400 can proceed to step S440, at which a portion of the second layer 512 is removed such that the second layer 512 remaining in the gap 520 is V-shaped and the gap 520 with the first layer 511 and the second layer 512 remaining therein slopes outward, as shown in FIG. 5D. In an embodiment, a portion of the second layer 512, e.g., the corners 512C of the second layer 512, as shown in FIG. 5C, can also be etched anisotropically solely in an ion bombardment process (e.g., sputtering, ion milling, etc.) such that the etched second layer 512 is V-shaped and the gap 520 with the first layer 511 and the second layer 512 remaining therein slopes outward. In an embodiment, only one cycle of deposition and ion bombardment (e.g., steps S410 and S420) is needed to be performed, e.g., if the gap 520 does not have too high an aspect ratio. In another embodiments, more than one cycle of deposition and ion bombardment (e.g., steps S410 to S440) may be needed to be performed, e.g., if the gap 520 has a high aspect ratio.

The method 400 can proceed to step S450, at which a third layer of the insulating material 513 is deposited in a third deposition process on the substrate 590 to cover the second layer 512 remaining in the gap 520 until the gap 520 is filled by the insulating material completely, as shown in FIG. 5E. The third deposition process can also include vapor-based deposition processes, such as ALD, PEALD, RPALD, CVD, PECVD, RPCVD, ICP CVD, HDP CVD, or others. The method 400 can include additional steps, such as removing a portion of the insulating material deposited outside of the gap 520, e.g., by chemical mechanical polishing (CMP), such that the insulating material is leveled with the adjacent features 580.

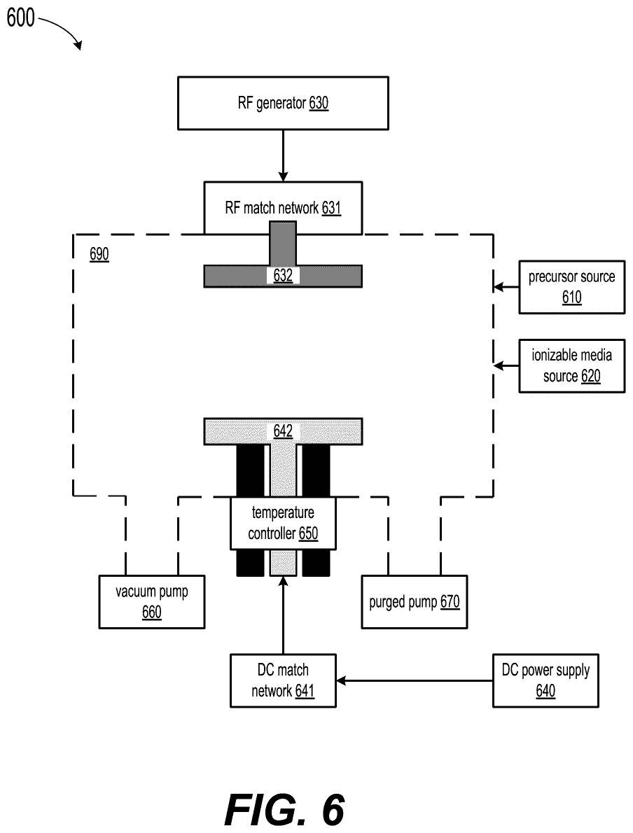

FIG. 6 is a schematic diagram illustrating an exemplary plasma system 600 that can fill a recessed feature of a semiconductor structure (e.g., the recessed feature 520 of the semiconductor structure 500) according to some embodiments of the present disclosure. In an embodiment, the plasma system 600 can implement the method 400 and be used in associated with a processing chamber (e.g., a plasma chamber) 690. The plasma chamber 690 can be nearly vacuumed by a vacuum system (e.g., a vacuum pump 660) and hold process gases in a low pressure (e.g., 10⁻³ mbar). In an embodiment, the plasma chamber 690 is not susceptible to etching from the process gases, and may be made of stainless steel, high-purity silica glass, or others.

The plasma system 600 can include a precursor source 610 coupled to the plasma chamber 690 that is configured to aerosolize precursor feedstocks (in solid, gas or liquid form) prior to introduction thereof into the plasma chamber 690. In an embodiment, the precursors may include chemical species capable of forming reactive species such as ions when ignited by electrical energy or when undergoing collisions with particles such as electrons. The precursors may include various reactive functional groups, such as acyl halide, amide, amino, etc.

The plasma system 600 can further include an ionizable media source 620 coupled to the plasma chamber 690 that is configured to introduce ionizable media feedstocks into the plasma chamber 690. The ionizable media feedstocks may be a liquid or a gas such as argon (Ar), helium (He), neon (Ne), nitrogen (N₂), oxygen (O₂), hydrogen (H₂), etc. The gases may be initially in a liquid form that can be gasified during application.

The plasma system 600 can further include a power source that is configured to produce power to ignite plasma feedstocks (including the aerosolized precursor feedstocks and the ionizable media feedstocks) to form plasma effluent containing ions, radicals, photons from the specific excited species and metastables that carry internal energy to drive desired chemical reactions in a workpiece (e.g., the semiconductor structure 500) or at a surface thereof that is positioned in the plasma chamber 690. In an embodiment, the power source can include an alternate current (AC) generator 630 and a direct current (DC) power supply 640. For example, the AC generator 630 can include a low frequency (LF) generator (e.g., 40 KHz), a radio frequency (RF) generator (e.g., 13.56 MHz, 27.12 MHz, etc.), a microwave generator (e.g., 2.45 GHz), etc. In an embodiment, the RF generator 630 can be an electrosurgical generator that is adapted to generate electrical power at a frequency from about 0.1 MHz to about 2,450 MHz, or more specifically from about 1 MHz to about 13.56 MHz. In another embodiment, the DC power supply 640 may be a continuous or pulsing DC power supply 640 that generates continuous or pulsing DC electrical energy, respectively.

The plasma system 600 can further include a first (or upper) electrode 632 and a second (or lower) electrode 642 that may be disposed parallel with or axially within the first electrode 632. In an embodiment, the second electrode 642 can include a workpiece holder for a workpiece (e.g., the semiconductor structure 500) to be placed thereon that can be heated to a desired temperature by a heater (or a temperature controller) 650. An electric field can be formed between the first electrode (or an active electrode) 632 and the second electrode (or a return or neutral electrode) 642 based on an AC voltage (e.g., an RF voltage) generated by the RF generator 630 and the DC voltage (e.g., a pulsing DC voltage) supplied by the DC power supply 640 to ignite the plasma feedstocks introduced into the plasma chamber 690 to generate plasma effluent for each specific surface treatment (e.g., etching) on the workpiece. For example, the second (or DC) electrode 642 can attract the atomic positive ions (e.g., Ar⁺. He⁺, etc.) and other species from the plasma effluent, and these ions may then bombard and etch the surface of the workpiece (e.g., the corners 511C of the first layer 511 and the corners 512C of the second layer 512 of the semiconductor structure 500). In some embodiments, the ion energy applied to and the angle distribution of the atomic positive ions can be controlled, e.g., by adjusting the RF voltage and/or the pulsing DC voltage, such that the etched first layer 511 and second layer 512 can have a desired V-shape.

The plasma system 600 can further include an RF match network 631 and a DC match network (e.g., a low pass filter or RF choke) 641 that can match the impedances of the load (i.e., the plasma effluent) to the RF generator 630 and the DC power supply 640, respectively. For example, at least one of the RF match network 631 and the DC match network 641 can include one or more reactive and/or capacitive components.

The plasma system 600 can further include a purged pump (e.g., a purged dry pump) 670 that is configured to pump away the atoms in a gas phase remaining in the plasma chamber 690.

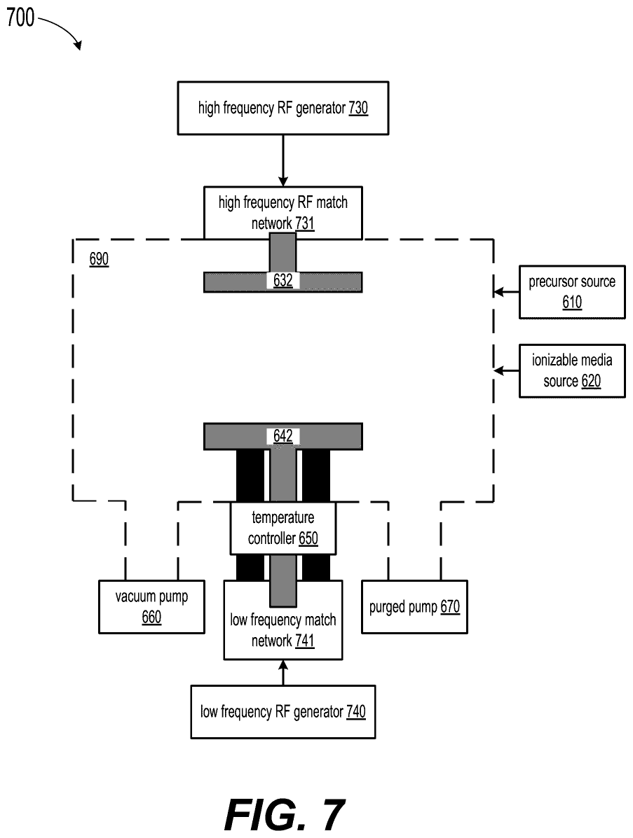

FIG. 7 is a schematic diagram illustrating an exemplary plasma system 700 that can also fill a recessed feature of a semiconductor structure (e.g., the recessed feature 520 of the semiconductor structure 500) according to some embodiments of the present disclosure. In an embodiment, the plasma system 700 can also implement the method 400 and be used in associated with the plasma chamber 690. The plasma system 700 can also include the precursor source 610, the ionizable media source 620, the first electrode 632, the second electrode 642, the temperature controller 650, the vacuum pump 660 and the purged pump 670. The plasma system 700 can further include a high frequency RF generator 730, a low frequency RF generator 740, and their respective high frequency RF match network 731 and low frequency RF match network 741. In an embodiment, the high frequency RF generator 730 can be used to generator a high frequency RF voltage to ignite the plasma feedstocks to form plasma effluent. In another embodiment, the low frequency RF generator 740 can be used to provide a low frequency RF bias voltage to the second electrode 642 such that the second (or low frequency RF) electrode 642 can attract the atomic positive ions (e.g., Ar⁺. He⁺, etc.) and other species from the plasma effluent, and these ions may then bombard and etch the surface of the workpiece (e.g., the corners 511C of the first layer 511 and the corners 512C of the second layer 512 of the semiconductor structure 500). In some embodiments, the ion energy applied to and the angle distribution of the atomic positive ions can be controlled, e.g., by adjusting the high frequency RF voltage and/or the low frequency RF voltage, such that the etched first layer 511 and second layer 512 can have a desired V-shape.

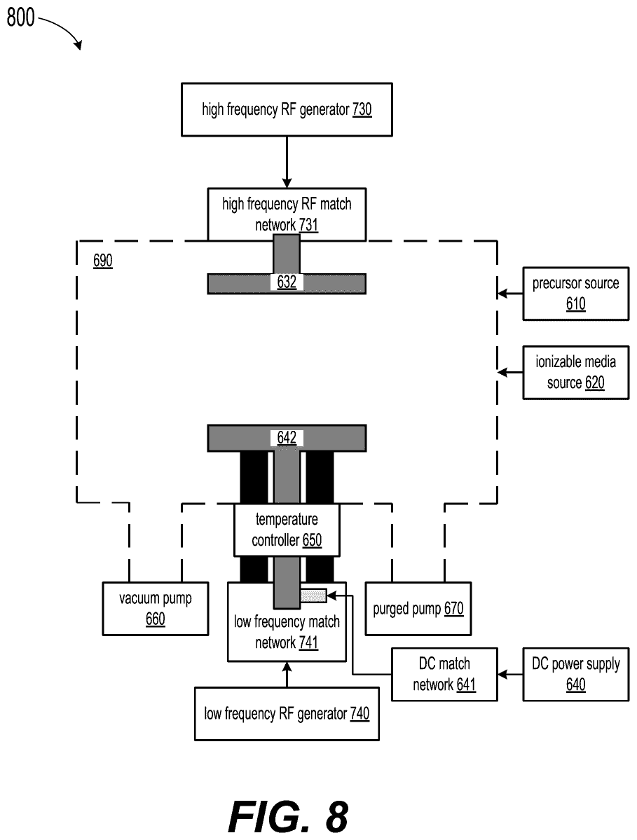

FIG. 8 is a schematic diagram illustrating an exemplary plasma system 800 that can also fill a recessed feature of a semiconductor structure (e.g., the recessed feature 520 of the semiconductor structure 500) according to some embodiments of the present disclosure. In an embodiment, the plasma system 800 can also implement the method 400 and be used in associated with the plasma chamber 690. The plasma system 800 can include all of the components of the plasma system 700, such as the high frequency RF generator 730 and the low frequency RF generator 740. The plasma system 800 can further include the DC power supply 640 and the DC match network 641 included in the plasma system 600. In an embodiment, the ion energy applied to and the angle distribution of the atomic positive ions can be controlled, e.g., by adjusting the high frequency RF voltage and/or the low frequency RF voltage and/or the DC voltage, such that the etched first layer 511 and second layer 512 can have a desired V-shape.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the present disclosure. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the present disclosure. Such variations are intended to be covered by the scope of this disclosure. As such, the foregoing descriptions of embodiments of the invention are not intended to be limiting. Rather, any limitations to embodiments of the invention are presented in the following claims.

What is claimed IS:

1. An inhibitor-free method for filling a recessed feature of a substrate, the inhibitor-free method comprising:
providing a substrate that has a recessed feature;
forming a first layer of an insulating material on the substrate to cover a sidewall and bottom of the recessed feature;
removing a portion of the first layer such that the recessed feature with the first layer remaining therein slopes outward: and
forming a second layer of the insulating material on the substrate to cover the first layer remaining in the recessed feature.

2. The inhibitor-free method of claim 1, further comprising:
removing a portion of the second layer such that the recessed feature with the first layer and the second layer remaining therein slopes outward.

3. The inhibitor-free method of claim 1, wherein the portion of the first layer include corners of the first layer.

4. The inhibitor-free method of claim 3, wherein the corners of the first layer contact with each other.

5. The inhibitor-free method of claim 4, wherein the insulating material includes SiN, and the first layer remaining in the recessed feature has a —NH₂ terminated surface at the corners that is modified to be a —N or —NH terminated surface so less growth is on the —N or —NH terminated surface at the corners than a bottom surface of the recessed feature which still has a —NH₂ terminated surface.

6. The inhibitor-free method of claim 1, wherein the portion of the first layer is removed in an ion bombardment process.

7. The inhibitor-free method of claim 6, wherein the ion bombardment process is included in a purely physical etch process.

8. The inhibitor-free method of claim 6, wherein ion energy applied to and angle distribution of atomic positive ions created in the ion bombardment process are controlled by adjusting an electrical field where the substrate is positioned therewithin.

9. The inhibitor-free method of claim 8, wherein the electrical field is formed between a first electrode and a second electrode that is coupled to the substrate, with a first alternating current (AC) voltage being applied to the first electrode and a second AC voltage or a direct current (DC) voltage being applied to the second electrode.

10. The inhibitor-free method of claim 9, wherein the first AC voltage includes a high radio frequency (RF) voltage, and the second AC voltage includes a low RF voltage.

11. The inhibitor-free method of claim 10, wherein the DC voltage includes a pulsing DC voltage.

12. A plasma system that is used in association with a plasma chamber to fill a recessed feature of a semiconductor structure, the plasma system comprising:
a first electrode disposed within the plasma chamber;
a first alternating current (AC) generator coupled to the first electrode, the first AC generate configured to generate and apply a first AC voltage to the first electrode;
a second electrode disposed within the plasma chamber; and
a second AC generator coupled to the second electrode, the second AC generator configured to generate and apply a second AC voltage to the second electrode,
wherein the first AC generator and the second AC generator are controlled to adjust the first AC voltage and the second AC voltage, respectively, such that ion energy applied to and angle distribution of atomic positive ions generated in the plasma chamber are controlled to anisotropically impact and remove a portion of an insulating material formed on a sidewall and bottom of a recessed feature of a semiconductor structure positioned within an electric field generated between the first electrode and the second electrode and the recessed feature with the insulating material remaining therein slopes outward.

13. The plasma system of claim 12, wherein the first AC generator includes a first radio frequency (RF) generator, the first AC voltage includes a first RF voltage, the second AC generator includes a second RF generator, and the second AC voltage includes a second RF voltage.

14. The plasma system of claim 13, wherein the second RF voltage has a lower frequency than the first RF voltage, and the semiconductor structure is coupled to the second electrode.

15. The plasma system of claim 14, further comprising:
a direct current (DC) power supply coupled to the second electrode, the DC power supply configured to supply a DC voltage to the second electrode,
wherein the DC power supply is controlled to adjust the DC voltage such that the ion energy applied to and the angle distribution of the atomic positive ions are further controlled to anisotropically impact and remove the portion of the insulating material formed on the sidewall and the bottom of the recessed feature of the semiconductor structure and the recessed feature with the insulating material remaining therein slopes outward.

16. The plasma system of claim 15, wherein the DC power supply includes a pulsing DC power supply, and the DC voltage includes a pulsing DC voltage.

17. A plasma system that is used in association with a plasma chamber to fill a recessed feature of a semiconductor structure, the plasma system comprising:
a first electrode disposed within the plasma chamber;
a first alternating current (AC) generator coupled to the first electrode, the first AC generate configured to generate and apply a first AC voltage to the first electrode;
a second electrode disposed within the plasma chamber; and
a direct current (DC) power supply coupled to the second electrode, the DC power supply configured to supply a DC voltage to the second electrode,
wherein the first AC generator and the DC power supply are controlled to adjust the first AC voltage and the DC voltage, respectively, such that ion energy applied to and angle distribution of atomic positive ions generated in the plasma chamber are controlled to anisotropically impact and remove a portion of an insulating material formed on a sidewall and bottom of a recessed feature of a semiconductor structure positioned within an electric field generated between the first electrode and the second electrode and the recessed feature with the insulating material remaining therein slopes outward.

18. The plasma system of claim 17, wherein the DC power supply includes a pulsing DC power supply, and the DC voltage includes a pulsing DC voltage.

19. The plasma system of claim 17, further comprising:
a second AC generator coupled to the second electrode, the second AC generator configured to generate and apply a second AC voltage to the second electrode,
wherein the second AC generator is controlled to adjust the second AC voltage such that the ion energy applied to and the angle distribution of the atomic positive ions are further controlled to anisotropically impact and remove the portion of the insulating material formed on the sidewall and the bottom of the recessed feature of the semiconductor structure and the recessed feature with the insulating material remaining therein slopes outward.

20. The plasma system of claim 19, wherein the first AC generator includes a first radio frequency (RF) generator, the first AC voltage includes a first RF voltage, the second AC generator includes a second RF generator, and the second AC voltage includes a second RF voltage.
